(19) United States
(12) Patent Application Publication
(10) Pub. No.: US 2025/0370067 A1
(43) Pub. Date: Dec. 4, 2025

(54) CABLE TESTER FOR POWER OVER ETHERNET CONFIGURATION

(71) Applicant: TSU YUAN MA, TAIPEI (TW)

(72) Inventor: TSU YUAN MA, TAIPEI (TW)

(21) Appl. No.: 19/078,839

(22) Filed: Mar. 13, 2025

(30) Foreign Application Priority Data
May 28, 2024 (TW) 113205479

(51) Int. Cl. G01R 31/58; G01R 31/40; G01R 31/66

(52) U.S. Cl. CPC G01R 31/58; G01R 31/40; G01R 31/66

(57) ABSTRACT

A cable tester for a Power over Ethernet configuration includes a PSE port connected through an Ethernet cable to a power sourcing equipment, a PD port connected through an internal connection circuit loop to the PSE port and connected through a device connection cable to a powered device, and a processing unit connected to the PSE port and the PD port. The processing unit communicates with the power sourcing equipment through the PSE port by executing a power supply determination algorithm, and establishes a power supplying agreement with respect to the powered device, based on a predetermined power supply protocol and a powered-end power supply protocol, so that the power sourcing equipment supplies an electrical power with a specific power range according to the power supplying agreement to the powered device. A voltage measurement unit is used to measure a voltage value of the electrical power delivered by the power sourcing equipment. A current measurement unit is used to measure a current value of the electrical power delivered by the power sourcing equipment to the powered device. A resistance test port is connected through a test circuit loop to the processing unit, so that the processing unit is allowed to carry out a resistance measurement and a conduction status test for a cable to be tested.

### BACKGROUND OF THE INVENTION

### 1. Field of the Invention

The present invention relates to a cable tester, and more particularly to a cable tester for a Power over Ethernet configuration.

### 2. The Related Arts

In the wired communication network technology, Power over Ethernet (PoE), capable of supplying electric power along with data to powered devices via Ethernet cabling, has gradually become popular due to its advantages such as low installation cost, simplified cabling arrangement, easy power supply, and feasible power management.

In the system architecture defined by Power over Ethernet, power sourcing equipment and a powered device are included. The power sourcing equipment is connected through Ethernet cables to one or more powered devices. The power sourcing equipment can be an end-span device (such as a network switch) or a mid-span device (such as a power supply device between a network switch and a powered device), so that the power sourcing equipment may supply electrical power through at least one twisted pair contained in the Ethernet cable to the powered device and manages the power supplied to the powered device. The powered device can be for example a monitor, a sales terminal, a lighting device, and the likes.

To use the system architecture of Power over Ethernet (POE), whether during system construction, wiring engineering, equipment installation, or subsequent maintenance, it is necessary to use appropriate inspection apparatuses or testers to test the connections between Ethernet cables, connectors, power sourcing equipment, and powered devices to ensure the stability of the system during future operation. Therefore, how to design a tester with simple operation, diverse inspection functions, and reliable inspection results has become an urgent need for this field of technology.

### SUMMARY OF THE INVENTION

Thus, an objective of the present invention is to provide a cable tester for Power over Ethernet configuration, which features the advantages of simple operation, diverse inspection functions, and reliable inspection results.

To achieve the objective, the present invention provides a cable tester for a Power over Ethernet configuration, which comprises a PSE port connected through an Ethernet cable to a power sourcing equipment, a PD port connected through an internal connection circuit loop to the PSE port and connected through a device connection cable to a powered device, and a processing unit connected to the PSE port and the PD port. The processing unit communicates with the power sourcing equipment through the PSE port by executing a power supply determination algorithm, and establishes a power supplying agreement with respect to the powered device, based on a predetermined power supply protocol and a powered-end power supply protocol, so that the power sourcing equipment supplies an electrical power with a specific power range according to the power supplying agreement to the powered device. A voltage measurement unit is used to measure a voltage value of the electrical power delivered by the power sourcing equipment. A current measurement unit is used to measure a current value of the electrical power delivered by the power sourcing equipment to the powered device. A resistance test port is connected through a test circuit loop to the processing unit, so that the processing unit is allowed to carry out a resistance measurement and a conduction status test for a cable to be tested.

In efficacy, with the Power-over-Ethernet cable tester according to the present invention, engineering or servicing personnel can easily carry out conduction status test and resistance measurement on a cable of a Power over Ethernet system, and also carry out tests on power supplying status, such as voltage and current of the supplied power.

The specific technology adopted in the present invention will be further described with reference to the embodiment provided below and the attached drawing.

### BRIEF DESCRIPTION OF THE DRAWINGS

FIG. 1 shows a functional block diagram of a circuit of the present invention.

### DETAILED DESCRIPTION OF THE PREFERRED EMBODIMENTS

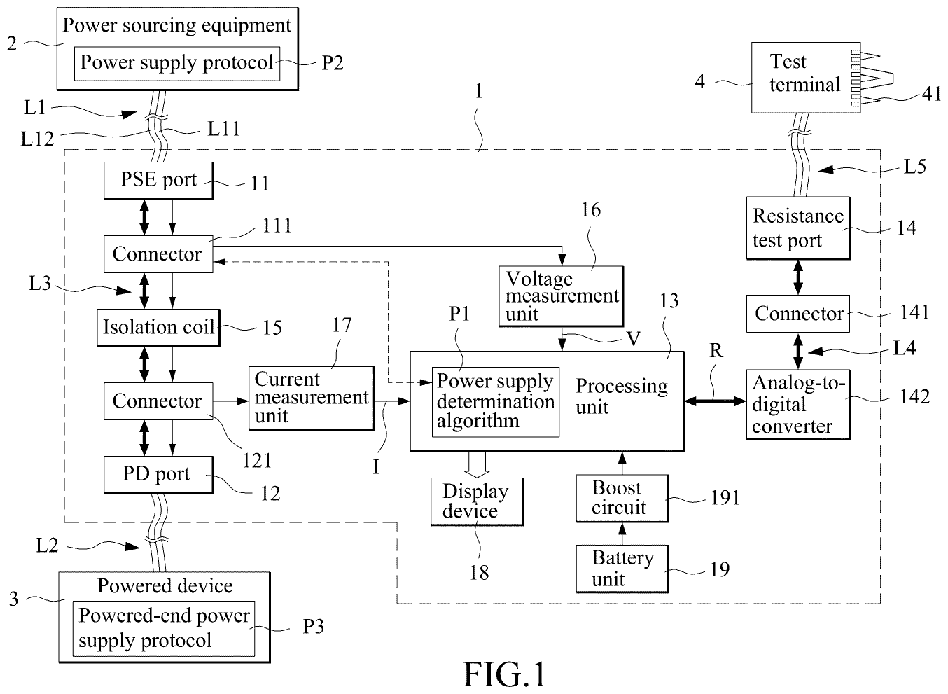

Referring to FIG. 1, a cable tester for Power over Ethernet configuration according to the present invention, generally designated at 1, comprises a power sourcing equipment (PSE) port 11, a powered device (PD) port 12, a processing unit 13, and a resistance test port 14.

During a cable test in a Power over Ethernet configuration, the PSE port 11 of the cable tester 1 is connected through an Ethernet cable L1 to a power sourcing equipment 2, and the PD port 12 is connected through a device connection cable L2 to a powered device 3.

The Ethernet cable L1 comprises at least one pair of data transmission lines L11 and at least one pair of power transmission lines L12, and the device connection cable L2 also comprises, correspondingly, at least one pair of data transmission lines and at least one pair of power transmission lines. A standard Ethernet cable (such as Cat5, Cat6, Cat7, or Cat8) contains a plurality of twisted pairs, of which at least one of the twisted pairs serve as the power transmission lines for transmitting electric power, while the remaining ones of the twisted pairs serve as the data transmission lines for transmitting data signals.

The PSE port 11 and the PD port 12 are respectively connected to standard connectors 111, 121 (such as RJ45 connectors), and are interconnected through an internal connection circuit loop L3, so that data signals can be transmitted between the power sourcing equipment 2 and the powered device 3 and the power sourcing equipment 2 can supply electrical power to the powered device 3. Preferably, the internal connection circuit loop L3 may comprise an isolation coil 15.

A processing unit 13 is connected through the connectors 111, 121 to the PSE port 11 and the PD port 12 respectively. A voltage measurement unit 16, a current measurement unit 17, and a display device 18 are connected to the processing unit 13. A battery unit 19 supplies electrical energy through a boost circuit 191 to the processing unit 13.

To carry out a PoE cable test, the processing unit 13 executes a power supply determination algorithm P1, where connection is made through the PSE port 11 to the power sourcing equipment 2, and a power supply agreement is established with respect to the powered device 3 (including, for example, determining whether the power sourcing equipment 2 and the powered device 3 are normally connected, the maximum power that the power sourcing equipment 2 can supply, the power demand of the powered device 3, and so on) based on a predetermined power supply protocol P2 and powered-end power supply protocol P3. After the power supply determination algorithm P1 is executed by the processing unit 13, the power sourcing equipment 2 supplies an electrical power with a specific power range to the powered device 3 according to the power supplying agreement and continuously monitors the power supply status thereof during the course of supplying power.

The voltage measurement unit 16 measures the voltage value V of the power delivered by the power sourcing equipment 2 through the connector 111, and transmits the voltage value V to the processing unit 13. The current measurement unit 17 measures the current value I of the power delivered by the power sourcing equipment 2 through the connector 121, and transmits the current value I to the processing unit 13. After receiving the voltage value V and the current value I, the processing unit 13 then calculates related values (such as electrical power), and transmits these values to display on the display device 18.

The resistance test port 14 is connected through a connector 141, a test circuit loop L4, and an analog-to-digital converter 142 to the processing unit 13. A test terminal 4 is connected through a cable-to-be-tested L5 to the resistance test port 14. The cable-to-be-tested L5 contains at least one twisted-pair cable, and the twisted-pair cable can be connected through a conductive wire 41 during testing.

To carry out a conduction status test of the cable-to-be-tested L5, the test terminal 4 is connected to the resistance test port 14. The processing unit 13 can then carry out testing on the conduction status of the at least one twisted-pair cable contained in the cable-to-be-tested L5, and carry out a resistance measurement to measure a conducting resistance value R of the cable-to-be-tested L5 through the analog-to-digital converter 142, the test circuit loop L4, and the connector 141. Preferably, specialized algorithm may be included in the present invention to ensure compliance with TIA/EIA-568 resistance requirements for stable data transmission and safe PoE power delivery. The conduction status and the resistance value R of the cable-to-be-tested L5 can be displayed on the display device 18.

By means of the resistance test port 14 and the test terminal 4, the Ethernet cable L1 or the device connection cable L2 can be tested by using the cable tester 1, allowing the cable tester 1 of the present invention to be applied to test the conduction status of each twisted pair contained in the Ethernet cable L1 and the device connection cable L2 and the conducting resistance value thereof.

The above-described embodiment is provided only for illustrating the structural arrangement of the present invention and is not intended to limit the scope of the present invention. Those skilled in the art may contemplate modifications and variations of the above-described embodiment within the structural arrangement and spirit of the present invention, and such variations are considered within the spirit of the present invention and the claims provided below. Thus, the scope of protection of the present invention is solely defined by the appended claims.

What is claimed is:

1. A cable tester for a Power over Ethernet configuration, comprising:
a power sourcing equipment (PSE) port connected through an Ethernet cable to a power sourcing equipment, wherein the Ethernet cable comprises at least one pair of data transmission lines and at least one pair of power transmission lines;
a powered device (PD) port connected through an internal connection circuit loop to the PSE port and connected through a device connection cable to a powered device;
a processing unit connected to the PSE port and the PD port, wherein the processing unit communicates with the power sourcing equipment through the PSE port by executing a power supply determination algorithm, and establishes a power supplying agreement with respect to the powered device based on a predetermined power supply protocol and a powered-end power supply protocol, so that after completion of the power supply determination algorithm, the power sourcing equipment supplies an electrical power with a specific power range according to the power supplying agreement to the powered device;
a voltage measurement unit connected to the processing unit, for measuring a voltage value of the electrical power delivered by the power sourcing equipment;
a current measurement unit connected to the processing unit, for measuring a current value of the electrical power delivered by the power sourcing equipment to the powered device; and
a resistance test port connected through a test circuit loop to the processing unit, so that the processing unit is allowed to carry out a resistance measurement and a conduction status test for a cable to be tested.

2. The cable tester according to claim 1, further comprising a test terminal connectable to the resistance test port, wherein the test terminal comprises at least a conductive wire for connecting at least one twisted-pair cable contained in the cable to be tested.

3. The cable tester according to claim 1, wherein the cable to be tested is one of the Ethernet cable and the device connection cable.

4. The cable tester according to claim 1, wherein the test circuit loop comprises an analog-to-digital converter connected between the resistance test port and the processing unit.

5. The cable tester according to claim 1, further comprising a display device connected to the processing unit to display the voltage value, the current value, and the resistance value.

6. The cable tester according to claim 1, further comprising a battery unit for supplying an electrical energy through a boost circuit to the processing unit.

7. The cable tester according to claim 1, wherein the internal connection circuit loop further comprises an isolation coil connected between the PSE port and the PD port.
